(19) United States
(12) Patent Application Publication
(10) Pub. No.: US 2009/0042126 A1
(43) Pub. Date: Feb. 12, 2009

(54) Photosensitive resin composition and cured article thereof

(76) Inventors: Ryutaro Tanaka, Tokyo (JP); Toru Kurihashi, Tokyo (JP); Hiroo Koyanagi, Tokyo (JP)

Correspondence Address: Nields & Lemack, 176 E. Main Street, Suite #5, Westboro, MA, 01581, US

(21) Appl. No.: 11/988,903

(22) PCT Filed: Jul. 20, 2006
(86) PCT No.: PCT/JP2006/314360

§ 371 Date: Mar. 4, 2008

(30) Foreign Application Priority Data
Aug. 1, 2005 (JP) 2005-222629

(51) Int. Cl. G03F 7/004

(52) U.S. Cl. 430/280.1

(57) ABSTRACT

A photosensitive resin composition which is excellent in photosensitivity and excellent in flame resistance, flexibility, adhesiveness, pencil hardness, resistance to solvent, acid resistance, heat resistance, resistance to gold plating and the like and a cured article thereof are provided.

An alkaline aqueous solution-soluble photosensitive resin composition containing an alkaline aqueous solution-soluble resin (A) obtained by adding a polybasic acid anhydride (c) to a resin (C) which is a reaction product of an epoxy resin (a) represented by the formula (1) with an unsaturated monocarboxylic acid (b), an epoxy resin (a′) represented by the formula (1) as a curing agent (B) and a photopolymerization initiator.

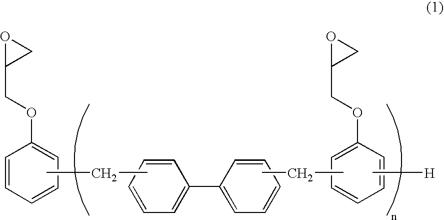

[In the formula, n represents a positive number of 1 to 10 as an average value.]

### TECHNICAL FIELD

The present invention relates to an alkaline aqueous solution-soluble photosensitive resin composition containing an alkaline aqueous solution-soluble resin obtained by modifying a specific epoxy compound, a specific epoxy resin and a photopolymerization initiator, and a cured product of the resin composition. More particularly, the invention relates to a resin composition yielding a cured product having excellent developability, non-halogen (not using halides) flame retardancy, flexibility, electrical insulating property, adhesiveness, solder heat resistance, chemical resistance, resistance to gold plating and the like, which cured product is useful as a solder resist for printed wiring boards, an interlayer insulating material for multilayer printed wiring boards, a solder resist for flexible printed wiring boards, a plating resist or the like, and a cured product of the resin composition.

### BACKGROUND ART

Photosensitive resin compositions using epoxycarboxylate compounds are excellently balanced in various properties such as thermal and mechanical properties, and adhesiveness to base materials, and thus have been used in the fields of paints and coatings, adhesives and the like. Recently, such resin composition are used in a wider range of industrial fields, such as in the applications for manufacturing electric and electronic elements, or in the applications for manufacturing printed wiring boards, with the range of applications being ever increasing.

However, concomitant to this enlargement of the range of applications, there is an increasing demand on the impartation of functions such as non-halogen flame retardancy, flexibility, electrical insulating properties, heat resistance and chemical resistance, to the photosensitive resin compositions using epoxycarboxylate compounds. Particularly with regard to flame retardancy, the requested property has been satisfied usually by employing a halide. However, as it is now required to take environmentally friendly measures, non-halogen flame retardancy is strongly demanded.

Among them, printed wiring boards are undergoing further development for high precision and high integration under the goal of achieving miniaturization and weight reduction of portable communication instruments or improvement in the data transmission speed, and along with the development, there also are demands for impartation of higher functions to solder resists, such as non-halogen flame retardancy, flexibility, electrical insulating properties, thermal resistance and chemical resistance. However, the currently used solder resists cannot cope with these demands.

Patent Document 1 describes an epoxy (meth)acrylate resin having a biphenyl skeleton, or polybasic acid anhydride modification products thereof, but does not have any description on a photosensitive resin composition having flame retardancy. Patent Document 2 describes a photosensitive resin composition containing an epoxy resin having a biphenyl skeleton, as a curing agent.

[Patent Document 1] Japanese Patent Application Laid-open No. 11-140144

[Patent Document 2] Japanese Patent Application Laid-open No. 2004-155916

### DISCLOSURE OF THE INVENTION

### Problems to be Solved by the Invention

It is an object of the present invention to provide a resin composition and a cured product having excellent properties such as excellent photosensitivity to active energy rays for the printing of sophisticated images; an ability for easy pattern formation upon development using a dilute alkaline aqueous solution; and non-halogen flame retardancy, flexibility, high insulating properties, good adhesiveness, chemical resistance, thermal resistance and resistance to electroless gold plating (resistance to gold plating) of a cured film obtained by thermally curing the resin composition in a post-cure process, to cope with the above high demands on performance for the applications in manufacturing highly functional printed wiring boards and the like.

### Means for Solving the Problems

The inventors of the present invention devotedly conducted research so as to achieve the above-described object and solve the problems, and as a result, completed the present invention. Specifically, the present invention relates to the following (1) to (7).

(1) An alkaline aqueous solution-soluble photosensitive resin composition comprising an alkaline aqueous solution-soluble resin (A) obtained by adding a polybasic acid anhydride (c) to a resin (C) which is a reaction product of an epoxy resin (a) represented by the formula (1) with an unsaturated monocarboxylic acid (b), and an epoxy resin (a′)represented by the formula (1) as a curing agent (B):

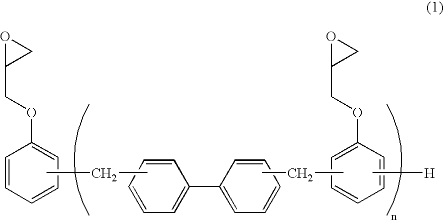

wherein n represents a positive number of from 1 to 10 as an average value.

(2) The alkaline aqueous solution-soluble photosensitive resin composition according to (1) above, further containing a resin (C′) which is a reaction product of an epoxy resin (a) represented by the formula (1) with an unsaturated monocarboxylic acid (b).

(3) The alkaline aqueous solution-soluble photosensitive resin composition according to (1) or (2) above, further containing a photopolymerization initiator and/or a reactive crosslinking agent.

(4) The alkaline aqueous solution-soluble photosensitive resin composition according to any one of (1) to (3) above, which is used as a solder resist.

(5) A cured product of the alkaline aqueous solution-soluble photosensitive resin composition according to any one of (1) to (4) above.

(6) A base material having a layer of the cured product according to (5) above.

(7) An article having the base material according to (6) above.

### BEST MODE FOR CARRYING OUT THE INVENTION

The alkaline aqueous solution-soluble photosensitive resin composition of the present invention contains an alkaline aqueous solution-soluble resin (A) obtained by adding a polybasic acid anhydride (c) to a resin (C) which is a reaction product of an epoxy resin (a) represented by the above-described formula (1) [wherein n represents a positive number of from 1 to 10 as an average value] with an unsaturated monocarboxylic acid (b), and an epoxy resin (a′) represented by the formula (1) as a curing agent (B).

According to the present invention, the epoxy resin represented by the above-described formula (1) is obtained by, for example, converting a compound represented by the following formula (2):

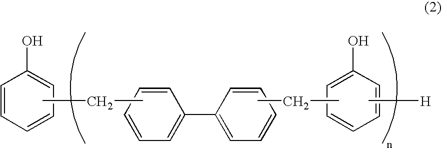

wherein n represents a positive number of from 1 to 10 as an average value, to a glycidyl ether. Examples of the compound represented by the formula (2) include commercially available compounds such as KAYAHARD GPH-65, KAYAHARD GPH-78, KAYAHARD GPH-103 (all manufactured by Nippon Kayaku Co., Ltd.), and the like.

Furthermore, examples of the epoxy resin represented by the above-described formula (1) include NC-3000, NC-3000H (all manufactured by Nippon Kayaku Co., Ltd.), as commercially available products, and the like.

It is desirable that the epoxy resin (a) used in the production of the alkaline aqueous solution-soluble resin (A) contained in the alkaline aqueous solution-soluble photosensitive resin composition of the present invention has an epoxy equivalent of 100 to 900 g/equivalent. If the epoxy equivalent is less than 100, the molecular weight of the obtained alkaline aqueous solution-soluble resin (A) is decreased so that film formation may become difficult, or sufficient flexibility may not be attained. Also, if the epoxy equivalent exceeds 900, the ratio of the unsaturated monocarboxylic acid (b) introduced is decreased so that the photosensitivity may be lowered.

The unsaturated monocarboxylic acid (b) used in the production of the alkaline aqueous solution-soluble resin (A) contained in the alkaline aqueous solution-soluble photosensitive composition of the present invention may be exemplified by, for example, acrylic acids or crotonic acid, α-cyanocinnamic acid, cinnamic acid, or a reaction product of a saturated or unsaturated dibasic acid with an unsaturated group-containing monoglycidyl compound.

Examples of the acrylic acids include (meth)acrylic acid, β-styrylacrylic acid, β-furfurylacrylic acid, half-esters which is an equimolar reaction product of a saturated or unsaturated dibasic acid anhydride with a (meth)acrylate derivative having one hydroxyl group in one molecule, half-esters which is an equimolar reaction product of a saturated or unsaturated dibasic acid with a monoglycidyl (meth)acrylate derivative, and the like.

More preferred examples of the unsaturated monocarboxylic acid (b) include (meth)acrylic acid, a reaction product of (meth)acrylic acid with ε-caprolactone, and cinnamic acid, from the viewpoint of the sensitivity when prepared into a photosensitive resin composition.

As the polybasic acid anhydride (c) used in the preparation of the alkaline aqueous solution-soluble resin (A) contained in the alkaline aqueous solution-soluble photosensitive resin composition of the present invention, any compound having one or more acid anhydride structures in the molecule can be used, and specific examples thereof include succinic anhydride, phthalic anhydride, trimellitic anhydride, pyromellitic anhydride, maleic anhydride, tetrahydrophthalic anhydride, hexahydrophthalic anhydride, ethylene glycol-bis(anhydrotrimellitate), glyceryl-bis(anhydrotrimellitate)monoacetate, 1,2,3,4-butanetetracarboxylic acid dianhydride, 3,3′,4,4′-diphenylsulfonetetracarboxylic acid dianhydride, 3,3′,4,4′-benzophenonetetracarboxylic acid dianhydride, 3,3′,4,4′-biphenyltetracarboxylic acid dianhydride, 3,3′,4,4′-diphenyl ether tetracarboxylic acid dianhydride, 2,2-bis(3,4-anhydrodicarboxyphenyl)propane, 2,2-bis(3,4-anhydrodicarboxyphenyl)hexafluoropropane, 5-(2,5-dioxotetrahydro-3-furanyl)-3-methylcyclohexene-1,2-dicarboxylic acid anhydride, 3a,4,5,9b-tetrahydro-5-(tetrahydro-2, 5-dioxo-3-furanyl)-naphtho [1,2-c]furane-1,3-dione and the like.

The alkaline aqueous solution-soluble resin (A) contained in the alkaline aqueous solution-soluble photosensitive resin composition of the present invention is obtained by subjecting a resin (C) in which an alcoholic hydroxyl group is generated by a reaction of the above-described epoxy compound (a) with an unsaturated monocarboxylic acid compound (b) (hereinafter, referred to as the first reaction), to a reaction with a polybasic acid anhydride (c) (hereinafter, referred to as the second reaction).

The first reaction can be performed without solvent, or in a solvent having no hydroxyl group, specifically for example, in a single or mixed organic solvent selected from ketones such as acetone, ethyl methyl ketone and cyclohexanone; an aromatic hydrocarbons such as benzene, toluene, xylene and tetramethylbenzene; glycol ethers such as ethylene glycol dimethyl ether, ethylene glycol diethyl ether, dipropylene glycol dimethyl ether, dipropylene glycol diethyl ether, triethylene glycol dimethyl ether and triethylene glycol diethyl ether; esters such as ethyl acetate, butyl acetate, methylcellosolve acetate, ethylcellosolve acetate, butylcellosolve acetate, carbitol acetate, propylene glycol monomethyl ether acetate, dialkyl glutarates (for example, dimethyl glutarate, etc.), dialkyl succinates (for example, dimethyl succinate, etc.) and dialkyl adipates (for example, dimethyl adipate, etc.); cyclic esters such as γ-butyrolactone; petroleum solvents such as petroleum ethers, petroleum naphtha, hydrogenated petroleum naphtha and solvent naphtha; as well as the reactive crosslinking agents that will be described later, and the like.

In this reaction the proportion of the raw material to be introduced is preferably set to use 80 to 120% equivalent of the unsaturated monocarboxylic acid compound (b), relative to one equivalent of the epoxy compound (a). If the proportion goes beyond this range, gelation may occur during the second reaction, or the thermal stability of the alkaline aqueous solution-soluble resin (A) may be decreased.

During the reaction, it is preferable to use a catalyst to accelerate the reaction, and specific examples of the catalyst include triethylamine, benzyldimethylamine, triethylammonium chloride, benzyltrimethylammonium bromide, benzyltrimethylammonium iodide, triphenylphosphine, triphenylstibine, methyltriphenylstibine, chromium octanoate, zirconium octanoate, and the like. In the case of using the catalyst, the amount of use is about 0.1 to 10% by weight based on the reactants. The reaction temperature is 60 to 150° C., and the reaction time is preferably 5 to 60 hours.

Furthermore, it is preferable to employ, as a thermal polymerization inhibitor, hydroquinone monomethyl ether, 2-methylhydroquinone, hydroquinone, diphenylpicrylhydrazine, diphenylamine, 2,6-di-t-butyl-p-cresol, and the like.

The first reaction is carried out while appropriately performing sampling, and the time point at which the acid value of the sample is 1 mg·KOH/g or less, and preferably 0.5 mg·KOH/g or less, is set as the termination point.

Additionally, in the present invention, the solids acid value is the amount (mg) of potassium hydroxide required in neutralizing the acidity of the carboxylic acid in 1 g of the resin, while the acid value is the amount (mg) of potassium hydroxide required in neutralizing 1 g of a solution containing the resin, and both are measured by a conventional neutralization titration method according to JIS K0070. Furthermore, if the concentration of the resin in the solution is known, the solids acid value can be determined by calculating from the acid value of the solution.

The second reaction is an esterification reaction performed after completion of the first reaction, by allowing the reaction solution to react with the above-described polybasic acid anhydride (c). The second reaction may be performed after separating the product of the first reaction, or the second reaction may be performed continuously without separating the product of the first reaction. In the case where a solvent is used in the second reaction, it is possible to use the same type of solvent as the solvent which can be used in the first reaction. Although the second reaction can be performed without catalyst, in order to accelerate the reaction, it is possible to use a basic catalyst (for example, pyridine, triethylamine, benzyldimethylamine, triethylammonium hydroxide, dimethylaminopyridine, and the like). In the case of using a catalyst, the amount of use may be 10% by weight or less based on the reactants. The reaction temperature is 40 to 120° C., and the reaction time is preferably 5 to 60 hours.

The alkaline aqueous solution-soluble resin (A) obtained by using a solvent can be isolated by removing the solvent from the alkaline aqueous solution-soluble resin (A) by an appropriate method.

The content ratio of the alkaline aqueous solution-soluble resin (A) contained in the alkaline aqueous solution-soluble photosensitive resin composition of the present invention is usually 15 to 70% by weight, and preferably 20 to 60% by weight, when the solids of the alkaline aqueous solution-soluble photosensitive resin composition is taken as 100% by weight.

When the epoxy resin (a′) represented by the above-described formula (1) as the curing agent (B) contained in the alkaline aqueous solution-soluble photosensitive resin composition of the present invention, is reacted under heating with the carboxyl group remaining in the resin coating film after photocuring, a cured coating film having stronger resistance to chemicals can be obtained.

The epoxy resin (a′) as the curing agent may be exemplified by the same type of compound as the epoxy resin (a) which is used in the production of the aforementioned alkaline aqueous solution-soluble resin (A), and the former compound may be identical to the latter. The resin has a softening point in the range of 30 to 120° C., and preferably 50 to 90° C. Furthermore, for the epoxy resin (a′) as the curing agent (B), n is more preferably 1 to 5 as an average value.

For the content of the curing agent (B) contained in the alkaline aqueous solution-soluble photosensitive resin composition of the present invention, it is preferably 50 to 200% of the equivalent calculated from the solids acid value of the alkaline aqueous solution-soluble resin (A) and the amount of use. If it exceeds 200%, the developability of the photosensitive resin composition of the present invention may be significantly reduced, and this is not preferable. The content ratio of the curing agent (B) contained in the alkaline aqueous solution-soluble photosensitive resin composition can vary depending upon the constituent of the composition and the acid value of the alkaline aqueous solution-soluble resin (A), but the content ratio is approximately 3 to 30% by weight based on the content of the solids of the alkaline aqueous solution-soluble photosensitive resin composition as 100% by weight.

The curing agent (B) may be mixed in advance in the alkaline aqueous solution-soluble photosensitive resin composition, but it is preferable to use the curing agent by mixing prior to application onto a printed wiring board or the like. That is, it is preferable to blend a base resin solution containing the aforementioned component (A) as the main component and a curing agent solution containing the curing agent (B) as the main component as a binary liquid type mixture, and mix the two solutions upon use.

The alkaline aqueous solution-soluble photosensitive resin composition of the present invention may contain a resin (C′) for the purpose of improving photosensitivity and controlling developability. The resin (C′) is not particularly limited as long as it is a reaction product of the epoxy resin (a) represented by the formula (1) and the unsaturated monocarboxylic acid (b), and the same resin as the above-described resin (C) may be mentioned, while the production method is also the same as described above. If the alkaline aqueous solution-soluble photosensitive resin composition contains the resin (C′), the content ratio is usually 3 to 40% by weight, and preferably 5 to 30% by weight, when the content of the solids in the alkaline aqueous solution-soluble photosensitive resin composition is taken as 100% by weight.

The alkaline aqueous solution-soluble photosensitive resin composition of the present invention may contain a photopolymerization initiator, and specific examples thereof include benzoins such as benzoin, benzoin methyl ether, benzoin ethyl ether, benzoin propyl ether and benzoin isobutyl ether; acetophenones such as acetophenone, 2,2-diethoxy-2-phenylacetophenone, 1,1-dichloroacetophenone, 2-hydroxy-2-methyl-phenylpropan-1-one, diethoxyacetophenone, 1-hydroxycyclohexyl phenyl ketone and 2-methyl-1-[4-(methylthio)phenyl]-2-morpholinopropan-1-one; anthraquinones such as 2-ethylanthraquinone, 2-tertiary-butylanthraquinone, 2-chloroanthraquinone and 2-amylanthraquinone; thioxanthones such as 2,4-diethylthioxanthone, 2-isopropylthioxanthone and 2-chlorothioxanthone; ketals such as acetophenonedimethylketal and benzyldimethylketal; benzophenones such as benzophenone, 4-benzoyl-4′-methyldiphenylsulfide and 4,4′-bismethylaminobenzophenone; phosphine oxides such as 2,4,6-trimethylbenzoyldiphenylphosphine oxide and bis(2,4,6-trimethylbenzoyl)phenylphosphine oxide; and the like. These photopolymerization initiators can be used individually or as mixtures of two or more species. In the case of using the photopolymerization initiator, the ratio of addition is usually 1 to 30% by weight, and preferably 2 to 25% by weight, when the content of the solids of the photosensitive resin composition is taken as 100% by weight.

Furthermore, reaction promoters such as tertiary amines such as triethanolamine and methyldiethanolamine, and benzoic acid derivatives such as N,N-dimethylaminobenzoic acid ethyl ester and N,N-dimethylaminobenzoic acid isoamyl ester, may be used in combination. In the case of using these reaction promoters, the amount of addition thereof is preferably 100% by weight or less based on the amount of addition of the photopolymerization initiator.

The alkaline aqueous solution-soluble photosensitive resin composition of the present invention may contain a reactive crosslinking agent, and specific examples thereof include 2-hydroxyethyl (meth)acrylate, 2-hydroxypropyl (meth)acrylate, 1,4-butanediol mono(meth)acrylate, carbitol (meth)acrylate, acryloylmorpholine, a half ester which is a reaction product of a hydroxyl group-containing (meth)acrylate (for example, 2-hydroxyethyl (meth)acrylate, 2-hydroxypropyl (meth)acrylate, 1,4-butanediol mono(meth)acrylate or the like) and an acid anhydride of a polycarboxylic acid compound (for example, succinic anhydride, maleic anhydride, phthalic anhydride, tetrahydrophthalic anhydride, hexahydrophthalic anhydride or the like), polyethylene glycol di(meth)acrylate, tripropylene glycol di(meth)acrylate, trimethylolpropane tri(meth)acrylate, trimethylolpropane polyethoxytri(meth)acrylate, glycerin polypropoxytri(meth)acrylate, di(meth)acrylate of an ε-caprolactone addition product of hydroxypivalic acid neopentyl glycol (for example, KAYARAD HX-220, HX-620 and the like manufactured by Nippon Kayaku Co., Ltd.), pentaerythritol tetra(meth)acrylate, poly(meth)acrylate of the reaction product of dipentaerythritol with ε-caprolactone, dipentaerythritol poly(meth)acrylate, epoxy (meth)acrylate which is a reaction product of a mono or polyglycidyl compound (for example, butyl glycidyl ether, phenyl glycidyl ether, polyethylene glycol diglycidyl ether, polypropylene glycol diglycidyl ether, 1,6-hexanediol diglycidyl ether, hexahydrophthalic acid diglycidyl ester, glycerin polyglycidyl ether, glycerin polyethoxyglycidyl ether, trimethylolpropane polyglycidyl ether, trimethylolpropane polyethoxypolyglycidyl ether or the like) and (meth)acrylic acid, and the like. In the case of containing a reactive crosslinking agent, the proportion of addition thereof is usually 2 to 40% by weight, and preferably 5 to 30% by weight, when the solids of the photosensitive resin composition is taken as 100% by weight.

If necessary, various additives, for example, a filler such as talc, barium sulfate, calcium carbonate, magnesium carbonate, barium titanate, aluminum hydroxide, aluminum oxide, silica or clay; a thixotropic agent such as Aerosil; a colorant such as phthalocyanine blue, phthalocyanine green and titanium oxide; silicone, fluorine-based leveling agent or a defoaming agent; a polymerization inhibitor such as hydroquinone or hydroquinone monomethyl ester; and the like, can be further added to the alkaline aqueous solution-soluble photosensitive resin composition of the present invention for the purpose of imparting various functions.

Furthermore, a thermal curing catalyst may be used for the alkaline aqueous solution-soluble photosensitive resin composition of the present invention, as a catalyst upon thermally curing the carboxyl group of the alkaline aqueous solution-soluble resin (A) and the epoxy group of the curing agent (B), and as the catalyst, melamine, imidazole, methylimidazole and the like may be mentioned. These thermal curing catalysts have an effect of suppressing oxidation of the substrate surface.

The alkaline aqueous solution-soluble photosensitive resin composition (liquid state or film state) of the present invention can be used as a resist material such as an interlayer insulating material for electronic parts, a solder resist for printed wiring boards, or coverlays, and also can be used as a color filter, a printing ink, a sealing agent, a paint, a coating agent, an adhesive or the like.

The alkaline aqueous solution-soluble photosensitive resin composition of the present invention can also be used as a dry film resist having a structure in which the resin composition is sandwiched between a support film and a protective film.

A cured product obtained by curing the above-described alkaline aqueous solution-soluble photosensitive resin composition of the present invention through irradiation with an energy ray such as an ultraviolet ray or an electron beam, is also included in the present invention. Curing through irradiation with an energy ray such as an ultraviolet ray can be performed by a conventional method, and for example, in the case of irradiating with ultraviolet rays, an ultraviolet ray generating apparatus such as a low pressure mercury lamp, a high pressure mercury lamp, an ultrahigh pressure mercury lamp, a xenon lamp or an ultraviolet emitting laser (excimer laser or the like) may be favorably used.

The film thickness of this cured product layer is about 0.5 to 160 μm, and preferably about 1 to 100 μm.

The cured product of the present invention is used in electric, electronic and optical base materials which may be exemplified by printed wiring boards, photoelectric boards or optical boards, for example, as a resist film or an interlayer insulating material for buildup type substrates, and these base materials are also included in the present invention. Specific examples of articles having these base materials include, for example, computer, electric appliances, portable instruments, and the like, and these articles are also included in the present invention.

The printed wiring board of the present invention can be obtained, for example, in the following manner. Specifically, according to necessity, a solution having the resin composition dissolved in a solvent which may be used in the production of the above-described resin (C) and can dissolve the resin composition, is prepared, and the alkaline aqueous solution-soluble photosensitive resin composition of the present invention is applied on a printing wiring board by methods such as a screen printing method, a spray method, a roll coating method, an electrostatic coating method and a curtain coating method, to a film thickness of 5 to 160 μm, and the coating is dried at a temperature of usually 50 to 110° C., and preferably 60 to 100° C., thereby forming a coating film. Thereafter, the coating film is directly or indirectly irradiated with an energy ray such as an ultraviolet ray through a photomask on which an exposure pattern has been formed, such as a negative film, at an intensity of usually about 10 to 2000 mJ/cm². The unexposed parts are developed using a developer solutions that will be described later, for example, by spraying, shaking immersion, brushing, scrubbing or the like. Thereafter, according to necessity, the coating film is further irradiated with ultraviolet rays, and then is subjected to a heat treatment (post-curing) at a temperature of usually 100 to 200° C., and preferably 140 to 180° C. As such, a printed wiring board having a permanent protective film which is excellent in non-halogen flame retardancy and resistance to gold plating, and satisfies various properties such as thermal resistance, chemical resistance, adhesiveness and flexibility, is obtained.

As the alkaline aqueous solution that can be used in developing as described above, inorganic alkaline aqueous solutions of potassium hydroxide, sodium hydroxide, sodium carbonate, potassium carbonate, sodium hydrogen carbonate, potassium hydrogen carbonate, sodium phosphate, potassium phosphate and the like, or organic alkaline aqueous solutions of tetramethylammonium hydroxide, tetraethylammonium hydroxide, tetrabutylammonium hydroxide, monoethanolamine, diethanolamine, triethanolamine and the like, may be mentioned.

Furthermore, since the alkaline aqueous solution-soluble resin composition of the present invention is soluble in the above-described solvents, in the case of using the resin composition in a solder resist, a plating resist or the like, developing can also be performed using the above-described solvents.

### EXAMPLES

Hereinafter, the present invention will be described in more detail by way of Examples, but the present invention is not intended to be limited to the following Examples.

### Synthesis Example 1

In a 1-L flask equipped with a stirring apparatus and a reflux condenser, 288.0 g of NC-3000H manufactured by Nippon Kayaku Co., Ltd. (a biphenyl type epoxy resin, epoxy equivalent: 215.0 g/equivalent, softening point: 69.2° C.) as an epoxy compound (a), 74.2 g of acrylic acid (molecular weight: 72.06) as an unsaturated monocarboxylic acid compound (b), 155.2 g of carbitol acetate as a reaction solvent, 1.552 g of 2,6-di-t-butyl-p-cresol as a thermal polymerization inhibitor, and 1.552 g of triphenylphosphine as a reaction catalyst were introduced, and the mixture was allowed to react at a temperature of 98° C. until the acid value of the reaction solution became 0.5 mg·KOH/g or less, to obtain an epoxy acrylate resin.

Subsequently, to this reaction solution, 112.4 g of carbitol acetate as a reaction solvent, and 134.8 g of tetrahydrophthalic anhydride as a polybasic acid anhydride (c) were introduced, and the mixture was allowed to react at 95° C. for 5 hours, to obtain a resin solution containing 65% by weight of an alkaline aqueous solution-soluble resin (A) (this solution is referred to as A-1). When the acid value was measured, the acid value was 67.0 mg·KOH/g (solids acid value: 103.1 mg·KOH/g).

### Synthesis Example 2

In a 1-L flask equipped with a stirring apparatus and a reflux condenser, 288.0 g of NC-3000H manufactured by Nippon Kayaku Co., Ltd. (a biphenyl type epoxy resin, epoxy equivalent: 215.0 g/equivalent) as an epoxy compound (a), 74.2 g of acrylic acid (molecular weight: 72.06) as an unsaturated monocarboxylic acid compound (b), 155.2 g of carbitol acetate as a reaction solvent, 1.552 g of 2,6-di-t-butyl-p-cresol as a thermal polymerization inhibitor, and 1.552 g of triphenylphosphine as a reaction catalyst were introduced, and the mixture was allowed to react at a temperature of 98° C. until the acid value of the reaction solution became 0.5 mg·KOH/g or less, to obtain an epoxy acrylate resin (C′) (this solution is referred to as C-1).

### Comparative Synthesis Example 1

In a 3-L flask equipped with a stirring apparatus and a reflux condenser, 860.0 g of EOCN-104S manufactured by Nippon Kayaku Co., Ltd. (a polyfunctional cresol novolac type epoxy resin, epoxy equivalent: 215.0 g/equivalent) as an epoxy compound, 288.3 g of acrylic acid (molecular weight: 72.06) as an unsaturated monocarboxylic acid compound (b), 492.1 g of carbitol acetate as a reaction solvent, 4.921 g of 2,6-di-t-butyl-p-cresol as a thermal polymerization inhibitor, and 4.921 g of triphenylphosphine as a reaction catalyst were introduced, and the mixture was allowed to react at a temperature of 98° C. until the acid value of the reaction solution became 0.5 mg·KOH/g or less, to obtain an epoxy carboxylate compound.

Subsequently, to this reaction solution, 169.8 g of carbitol acetate as a reaction solvent, and 201.6 g of tetrahydrophthalic anhydride as a polybasic acid anhydride (c) were introduced, and the mixture was allowed to react at 95° C. for 5 hours, to obtain a resin solution containing 67% by weight of the alkaline aqueous solution-soluble resin described in Synthesis Example 1 of Patent Document 2 (this solution is referred to as X-1). When the acid value was measured, the acid value was 69.4 mg·KOH/g (solids acid value: 103.6 mg·KOH/g).

### Examples 1 and 2, and Comparative Examples 1 and 2

Using the (A-1), (C-1) and (X-1) obtained in the above-described Synthesis Examples 1 and 2 and the Comparative Example 1, as well as NC-3000 manufactured by Nippon Kayaku Co., Ltd. (a biphenyl type epoxy resin, epoxy equivalent: 272 g/equivalent) having the structure of the above-described formula (1) and EOCN-104S manufactured by Nippon Kayaku Co., Ltd. (a polyfunctional cresol novolac type epoxy resin, epoxy equivalent: 215.0 g/equivalent) as curing agents (B), the components were mixed at the respective blending proportions indicated in Table 1, and the mixture was kneaded in a triple roll mill, to obtain a photosensitive resin composition.

This was applied onto a printed wiring board by a screen printing method so that a dried film thickness of 15 to 25 μm was attained, and the coating film was dried in a hot air dryer at 80° C. for 30 minutes. Subsequently, the coating film was irradiated with an ultraviolet ray through a mask on which a circuit pattern was formed using an ultraviolet exposure apparatus (ORC Manufacturing Co., Ltd., Model W-680GW), and spray developing was performed using a 1% aqueous solution of sodium carbonate, to remove the resin on the ultraviolet-unirradiated parts. After washing with water and drying the film, the printed board was subjected to a thermal curing reaction in a hot air dryer at 150° C. for 60 minutes to obtain a cured film. For the obtained cured product, testing for tackiness, developability, resolution properties, photosensitivity, surface gloss, flame retardancy, substrate warpage, flexibility, adhesiveness, pencil hardness, solvent resistance, acid resistance, thermal resistance and resistance to gold plating was performed. The results are presented in Table 2.

TABLE 1

| | |
|---|---|
| | Comparative |
| Example | Example |

| | | 1 | 2 | 1 | 2 |
|---|---|---|---|---|---|
| Alkaline aqueous | | | | | |
| solution-soluble | | | | | |
| resin solution | | | | | |
| A-1 | | 46.55 | 36.55 | | 46.55 |
| X-1 | | | | 46.55 | |
| Epoxy acrylate | | | | | |
| resin solution | | | | | |
| C-1 | | | 10.00 | | |
| Reactive crosslinking | | | | | |
| agent | | | | | |
| DPHA | *1 | 6.06 | 6.06 | 6.06 | 6.06 |
| Photopolymerization | | | | | |
| initiator | | | | | |
| Irgacure-907 | *2 | 4.54 | 4.54 | 4.54 | 4.54 |
| DETX-S | *3 | 0.91 | 0.91 | 0.91 | 0.91 |
| Curing agent (B) | | | | | |
| NC-3000 | | 17.62 | 17.62 | 17.62 | |
| EOCN-104S | *4 | | | | 17.62 |
| Thermal curing | | | | | |
| catalyst | | | | | |
| Melamine | | 0.76 | 0.76 | 0.76 | 0.76 |
| Additives | | | | | |
| Barium sulfate | | 24.22 | 24.22 | 24.22 | 24.22 |
| Phthalocyanine blue | | 0.61 | 0.61 | 0.61 | 0.61 |
| BYK-354 | *5 | 0.39 | 0.39 | 0.39 | 0.39 |
| KS-66 | *6 | 1.21 | 1.21 | 1.21 | 1.21 |
| Solvent | | | | | |
| Carbitol acetate | | 4.54 | 4.54 | 4.54 | 4.54 |

(Notes)
*1 manufactured by Nippon Kayaku Co., Ltd.: dipentaerythritol hexaacrylate
*2 manufactured by Ciba Specialty Chemicals, Inc.: 2-methyl-1-[4-(methylthio)phenyl]-2-morpholinopropan-1-one
*3 manufactured by Nippon Kayaku Co., Ltd.: 2,4-diethylthioxanthone
*4 manufactured by Nippon Kayaku Co., Ltd.: cresol novolac type epoxy resin
*5 manufactured by BYK Chemie GmbH: leveling agent
*6 manufactured by Shin-Etsu Chemical Co., Ltd.: defoaming agent

The testing methods and evaluation methods are as follows.

(Tackiness) Absorbent cotton was spread over the film obtained after applying the composition on the substrate and dried, and tackiness of the film was evaluated.

Evaluation Criteria

◯ The absorbent cotton waste does not stick.

× The absorbent cotton waste sticks to the film.

(Developability) The following evaluation criteria were used.

Evaluation Criteria

◯ At the time of developing, developing was performed with ink being completely removed.

× At the time of developing, there are undeveloped parts.

(Resolution properties) To the coating film after drying, a negative pattern of 50 μm is adhered, and exposure by irradiation with an ultraviolet ray at an integrated dose of 200 mJ/cm² is conducted. Subsequently, developing is performed using a 1% aqueous solution of sodium carbonate for 60 seconds, at a spray pressure of 2.0 kg/cm², and the transferred pattern is observed under a microscope. The following criteria were used.

Evaluation Criteria

◯ Resolved pattern has straight line edges.

× Peel-off occurs, or the pattern edges are irregular.

(Photosensitivity) To the coating film after drying, 21 stages of step tablet (Kodak, Inc.) were adhered, and exposure by irradiation with an ultraviolet ray at an integrated dose of 500 mJ/cm² is conducted. Subsequently, developing is performed using a 1% aqueous solution of sodium carbonate for 60 seconds, at a spray pressure of 2.0 kg/cm², and the number of stages of coating film remaining after the developing is checked.

(Surface gloss) To the coating film after drying, exposure by irradiation with an ultraviolet ray at 500 mJ/cm² is conducted. Subsequently, developing is performed using a 1% aqueous solution of sodium carbonate for 60 seconds, at a spray pressure of 2.0 kg/cm², and the cured film after drying is observed. The following criteria were used.

Evaluation Criteria

◯ Clouding is not detected at all.

× Slight clouding is detected.

(Flame retardancy) After curing, the base material is removed, and strips having a width of 1 cm are prepared using a film of resin only. The strips are ignited, and the phenomenon until extinguishing is observed.

Evaluation Criteria

◯ Extinguished.

× Burned up.

(Substrate warpage) The following criteria were used.

Evaluation Criteria

◯ Warpage is not detected in the substrate.

Δ The substrate is minimally warped.

× Substrate warpage is detected.

(Flexibility) The cured film is bent 180° and observed. The following criteria were used.

Evaluation Criteria

◯ Cracks are not detected on the film surface.

× The film surface cracks.

(Adhesiveness) According to JIS K5400, one hundred cross cuts with 1 mm-long sides were made on a test specimen, and a peeling test was performed using Cellotape (registered trademark). The peeled state of the cross cuts was observed, and evaluated according to the following criteria.

Evaluation Criteria

◯ No peeling.

× Peeling occurs.

(Pencil hardness) Evaluation was performed according to JIS K5400.

(Solvent resistance) A test specimen is immersed in isopropyl alcohol at room temperature for 30 minutes. After checking as to whether there is any abnormality in the external appearance, a peeling test was performed using Cellotape (registered trademark), and evaluated according to the following criteria.

Evaluation Ccriteria

◯ There is no abnormality in the external appearance of the coating film, and swelling or peeling does not occur.

× There is swelling or peeling in the coating film.

(Acid resistance) A test specimen is immersed in a 10% aqueous hydrochloric acid solution at room temperature for 30 minutes. After checking as to whether there is any abnormality in the external appearance, a peeling test was performed using Cellotape (registered trademark), and evaluated according to the following criteria.

Evaluation Criteria

◯ There is no abnormality in the external appearance of the coating film, and swelling or peeling does not occur.

× There is swelling or peeling in the coating film.

(Thermal resistance) A test specimen was coated with rosin flux, and immersed in a solder bath at 260° C. for 5 seconds. While defining this as one cycle, three cycles were repeated, and then cooled to room temperature. A peeling test was conducted using Cellotape (registered trademark), and the specimen was evaluated according to the following criteria.

Evaluation Criteria

◯ There is no abnormality in the external appearance of the coating film, and swelling or peeling does not occur.

× There is swelling or peeling in the coating film.

(Resistance to gold plating) A test substrate was immersed in an acidic degreasing solution (manufactured by Nippon McDermid Co., Ltd., a 20 vol % aqueous solution of Metex L-5B) at 30° C. for 3 minutes, and then washed with water. Subsequently, the test substrate was immersed in a 14.4 wt % aqueous solution of ammonium persulfate for 3 minutes, and then washed with water. Furthermore, the test substrate was immersed in a 10 vol % aqueous sulfuric acid solution at room temperature for 1 minute, and then washed with water. Subsequently, this substrate was immersed in a catalyst solution (manufactured by Meltex, Inc., a 10 vol % aqueous solution of Metal Plate Activator 350) at 30° C. for 7 minutes, washed with water, immersed in a nickel plating solution (manufactured by Meltex, Inc., a 20 vol % aqueous solution of Melplate Ni-865M, pH 4.6) at 85° C. for 20 minutes, to perform nickel plating. Then, the test substrate was immersed in a 10 vol % aqueous sulfuric acid solution at room temperature for 1 minute, and washed with water. Subsequently, the test substrate was immersed in a gold plating solution (manufactured by Meltex, Inc., an aqueous solution of 15 vol % of Aurolectroless UP and 3 vol % gold potassium cyanide, pH 6) at 95° C. for 10 minutes, to perform electroless gold plating, and then washed with water. The test substrate was immersed in hot water at 60° C. for 3 minutes, washed with water, and dried. Cellophane adhesive tape was attached to the obtained electroless gold plated substrate, and the state of when the adhesive tape was peeled off was observed.

Evaluation Criteria

◯ No abnormality was observed.

× Slight peeling was observed.

(PCT resistance) The test substrate was left to stand in water at 121° C. under 2 atmospheres for 96 hours, and was checked for abnormality in the external appearance. A peeling test was performed using Cellotape (registered trademark), and the test substrate was evaluated according to the following criteria.

Evaluation Criteria

◯ There is no abnormality in the external appearance of the coating film, and swelling or peeling does not occur.

× There is swelling or peeling in the coating film.

(Thermal impact resistance) A test specimen was subjected to thermal hysteresis composed of 1 cycle of 30 minutes at −55° C. and 30 minutes at 125° C. After completing 1000 cycles, the test specimen was observed under a microscope, and was evaluated according to the following criteria.

Evaluation Criteria

◯ No cracks were generated in the coating film.

× Cracks were generated in the coating film.

TABLE 2

| | |
|---|---|
| | Comparative |
| Example | Example |

| Evaluation item | 1 | 2 | 1 | 2 |
|---|---|---|---|---|
| Tackiness | ∘ | ∘ | ∘ | ∘ |
| Developability | ∘ | ∘ | ∘ | ∘ |
| Resolution properties | ∘ | ∘ | ∘ | ∘ |
| Photosensitivity | 7 | 9 | 9 | 7 |
| Surface gloss | ∘ | ∘ | ∘ | ∘ |
| Flame retardancy | ∘ | ∘ | x | x |
| Substrate warpage | ∘ | ∘ | x | Δ |
| Flexibility | ∘ | ∘ | x | x |
| Adhesiveness | ∘ | ∘ | ∘ | ∘ |
| Pencil hardness | 6H | 6H | 7H | 6H |
| Solvent resistance | ∘ | ∘ | ∘ | ∘ |
| Acid resistance | ∘ | ∘ | x | x |
| Thermal resistance | ∘ | ∘ | ∘ | ∘ |
| Resistance to gold plating | ∘ | ∘ | ∘ | ∘ |
| PCT resistance | ∘ | ∘ | x | ∘ |
| Thermal impact resistance | ∘ | ∘ | x | ∘ |

As is obvious from the above results, the alkaline aqueous solution-soluble photosensitive resin composition of the present invention is not tacky but is highly sensitive, and the cured film thereof has excellent flame retardancy, flexibility, solder heat resistance, chemical resistance, resistance to gold plating and the like. Furthermore, no cracks are generated on the surface of the cured product, and the cured product shows a feature that even in the case of using a thinned substrate, the warpage of the substrate is small. On the other hand, the resin composition and the cured product according to an Example of Patent Document 2, which is described as Comparative Example 1 in the present Specification, does not exhibit flame retardancy, and is inferior to the resin composition of the present invention and the cured product in the substrate warpage, flexibility, acid resistance, PCT resistance or thermal impact resistance. Furthermore, the resin composition and the cured product of Comparative Example 2 using a curing agent (B) which is different from that of the alkaline aqueous solution-soluble photosensitive resin composition of the present invention, does not exhibit flame retardancy, and is inferior to the resin composition and the cured product of the present invention in the flexibility and acid resistance.

### Example 3

### Preparation of Dry Film

54.44 g of a resin obtained by changing only the solvent of the alkaline aqueous solution-soluble resin solution (A-1) described in Synthesis Example 1 to propylene glycol monomethyl ether, 3.54 g of DPCA-60 (trade name; manufactured by Nippon Kayaku Co., Ltd.) as a crosslinking agent, 4.72 g of Irgacure-907 (manufactured by Ciba Specialty Chemicals) and 0.47 g of Kayacure-DETX-S (manufactured by Nippon Kayaku Co., Ltd.) as photopolymerization initiators, 14.83 g of NC-3000 (manufactured by Nippon Kayaku Co., Ltd.) as a curing agent, 1.05 g of melamine as a thermal curing catalyst, and 20.95 g of methyl ethyl ketone as a concentration adjusting solvent were added, and the mixture was kneaded in a bead mill to be uniformly dispersed. Thus, a resist resin composition was obtained.

Subsequently, the resin composition was uniformly applied to a polyethylene terephthalate film which served as a support film, by a roll coating method, and the coating was passed through a hot air drying furnace at a temperature of 70° C. to form a resin layer having a thickness of 30 μm. Apolyethylene film as a protective film was attached onto this resin layer, to obtain dry film. The obtained dry film was attached to a polyimide printed board (copper circuit thickness: 12 μm, polyimide film thickness: 25 μm) using a heating roll at a temperature of 80° C., such that the resin layer is attached over the entire surface of the substrate while peeling off the protective film. The dry film was irradiated with ultraviolet rays through a mask onto which a circuit pattern was formed, using an ultraviolet exposure apparatus (manufactured by ORC Manufacturing Co., Ltd., Model HMW-680GW). Spray developing was performed using a 1% aqueous solution of sodium carbonate, to remove the ultraviolet-unirradiated parts of the resin. The printed board was washed with water, dried and subjected to a curing reaction under heating in a hot air dryer at 150° C. for 60 minutes, to obtain a cured film.

### INDUSTRIAL APPLICABILITY

The alkaline aqueous solution-soluble photosensitive resin composition containing an alkaline aqueous solution-soluble resin (A) obtained by adding a polybasic acid anhydride (c) to a resin (C) which is a reaction product of an epoxy resin (a) represented by the above-described formula (1) and an unsaturated monocarboxylic acid (b), and an epoxy resin (a′) represented by the above-described formula (1) as a curing agent (B), has excellent tackiness and photosensitivity, and can form a pattern by developing using an alkaline aqueous solution. Also, a cured product thereof has excellent functions such as non-halogen flame retardancy, flexibility, electric insulating property, heat resistance and chemical resistance, and thus is appropriate to be used in printed wiring boards as a solder resist.

1. An alkaline aqueous solution-soluble photosensitive resin composition comprising an alkaline aqueous solution-soluble resin (A) obtained by adding a polybasic acid anhydride (c) to a resin (C) which is a reaction product of an epoxy resin (a) represented by the formula (1) with an unsaturated monocarboxylic acid (b), and an epoxy resin (a′) represented by the formula (1) as a curing agent (B): 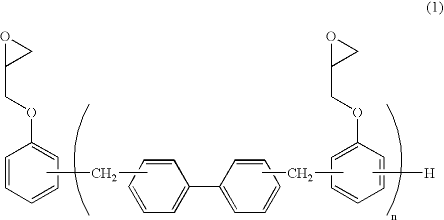
wherein n represents a positive number of from 1 to 10 as an average value.

2. The alkaline aqueous solution-soluble photosensitive resin composition according to claim 1, further comprising a resin (C′) which is a reaction product of an epoxy resin (a) represented by the formula (1) with an unsaturated monocarboxylic acid (b).

3. The alkaline aqueous solution-soluble photosensitive resin composition according to claim 1 or 2, further comprising a photopolymerization initiator and/or a reactive crosslinking agent.

4. The alkaline aqueous solution-soluble photosensitive resin composition according to any one of claims 1 to 3, which is used as a solder resist.

5. A cured product of the alkaline aqueous solution-soluble photosensitive resin composition according to any one of claims 1 to 4.

6. A base material having a layer of the cured product according to claim 5.

7. An article having the base material according to claim 6.
